(19) United States
(12) Patent Application Publication
(10) Pub. No.: US 2007/0001185 A1
(43) Pub. Date: Jan. 4, 2007

(54) LED backlight module

(76) Inventors: Ying Tsung Lu, Hsinchu Hsien (TW); Cheng Lin Yang, Hsinchu (TW); Pong Lai, Hsinchu (TW); Ching Chin Wu, Hsinchu (TW)

Correspondence Address: RABIN & BERDO, P.C.;Suite 500, 1101 14th Street, N.W., Washington, DC, 20005, US

(21) Appl. No.: 11/435,842

(22) Filed: May 18, 2006

(30) Foreign Application Priority Data
Jun. 29, 2005 (TW) 094121812
Nov. 29, 2005 (TW) 094141839

(51) Int. Cl. H01L 33/00

(52) U.S. Cl. 257/98

(57) ABSTRACT

A LED backlight module including a diffusion plate, at least an optical devices, at least a light-emitting diode and a second reflection surface is provided. The optical device is provided underneath the diffusion plate and has a first reflection surface. The light-emitting diode is provided underneath the optical device, for emitting light to the first reflection surface where first reflection of the light is performed. The second reflection surface is provided underneath the light-emitting diode, for receiving the light of the first reflection and performing second reflection of the received light. By controlling light paths of LED with the optical devices, light emitted from LED may be leaded to a specific direction instead of directly emitting from a front surface of LED, so as to achieve the performance of color-mixing and uniform distribution.

### FIELD OF THE INVENTION

The present invention relates to backlight modules, and more particularly, to a backlight module using a light-emitting diode (LED) as a light source.

### BACKGROUND OF THE INVENTION

The amount of liquid crystal display televisions (LCD TVs) is reportedly estimated to achieve at a level of at least 16.24 millions in 2006 due to a strong demand of LCD TVs in the future (Display Search). There is therefore another commercial chance generated for raw materials and devices in LCD key component industries, and among them a backlight module is especially one of the important developing elements. In accordance with environmental protections and a trend of using a compact backlight source in a backlight module, a cold cathode fluorescent lamp (CCFL) is going to be gradually replaced by a light-emitting diode (LED) and the characteristic of a light source is changed from a line source such as a CCFL to a point source such as a LED.

Therefore, in the development of next generation backlight sources, the characteristics of “high resolution”, “high luminescence”, “mercury-free”, “high color reproducibility” provided by a backlight module using a LED light source can raise an additional value to a liquid crystal display instead of merely giving an impression of “space-saving” of conventional LED. Thereby, it is generally believed that the applications of a LED backlight module can be extended to portable electronic products from now on, and can be spread rapidly into various industry fields such as automobiles, commercial light boxes, displays, video mediums such as TV, information, communications, household electronics, consumers and the like. Meanwhile, present biggest challenge encountered in using LED as a backlight source is how to uniformly diffuse the light of a point-source, single-color LED to the entire surface and obtain uniform color and luminance. Related technical patents include U.S. Pat. No. 5,499,120 and U.S. Patent Publication No. 2005/0001537.

According to U.S. Pat. No. 5,499,120, LEDs with broad light angle are arranged into a matrix to serve as a backlight of LCD. However, since the LEDs of such backlight module are arranged regularly and do not have any optical devices for controlling light paths of LEDs, it is not able to perform a color-mixing process. Thus, the technique is applied only to singe-color light sources and would not obtain a colorizing effect.

Furthermore, U.S. Patent Publication No. 2005/0001537 proposes a technique for applying total internal reflection (TIR) theory to LED. A specific optical device structure that satisfies TIR angle is used to direct the light emitted from LED chips of different colors to emit from a side surface thereof, so as to achieve color-mixing and uniform distribution.

However, the optical device structure used in this patent must satisfy the threshold angle requirement of the TIR theory, which is extremely complicated in designing. Furthermore, the optical device structure can only afford a small tolerance. Therefore, complicated tooling structures should be needed, which leads to the difficulty in production and increases costs due to a requirement of using a plurality of tooling molds for production.

Moreover, it is real hard to satisfy the requirement of the TIR theory. Once the position of the LED chip is misaligned with the corresponding position of the TIR surface, light would emit from the front surface. Therefore, products manufactured by substantially executing this technique cannot completely direct light to emit from a side surface, which leads to non-uniform emitting light.

Furthermore, since a small portion of light will emit from the front surface of the LED using the structure of this technique, two diffusion plates should be provided in the entire module in order to improve the uniformity of emitting light. And an additional small spot reflector should be added on the top surface of LED for complete shielding and satisfying the threshold angle requirement of TIR. That is, a structure of stacking a lot of layers should be employed to improve the uniformity problem of emitting light in the foresaid patent. Therefore, the LED backlight module using the technique of this patent has problems of complicated structure, manufacturing difficulty, and high costs, which is disadvantageous to industry application and needs further improvements.

Besides, typical package structures of LEDs include a sink type and an overhead type (protrudent type) LED package structure, which generate different output light angles according to different package structures. For example, in an overhead type LED package structure, light generated by the LED will be directly emitted from a region within 180 degrees. Thus, the optical devices provided over the LED chip should only reflect the light outputted from the front of the LED chip. On the contrary, in a sinking type LED package structure, since primary output regions are shielded, the light generated by the LED chip will be deflected to generate special output light angles. However, the special optical devices used in the foresaid patent only provide specific refraction angles, which are not able to satisfy both the sinking type and the overhead type LED package structures and have no applicability in multiple purposes.

Since the above conventional technology having problems of not able to achieve colorizing, having non-uniform output light, having complicated structures, difficult to be manufactured, having higher cost, and not having industrial applicability, it is thus an urgent task to provide a simple and easily producible structure and a lower cost to enhance color-mixing property and uniformity of a backlight module, so as to increase the industrial applicability and solve the problems generated by conventional technology.

### SUMMARY OF THE INVENTION

In view of the above defects of conventional technology, a primary objective of the present invention is to provide a LED backlight module to enhance the performance of color-mixing and uniform distribution.

Another objective of the present invention is to provide a LED backlight module having a simple and easily producible structure.

Yet another objective of the present invention is to provide a LED backlight module that may reduce manufacturing cost.

Another objective of the present invention is to provide a LED backlight module that may increase the industrial applicability.

To achieve the above objectives, the present invention provides a LED backlight module, wherein the LED backlight module includes a diffusion plate, one or more optical devices, one or more light-emitting diodes, and a reflection sheet. The diffusion plate is used to uniformly diffuse light. Each of the optical devices is provided underneath the diffusion plate and has a reflection surface of high reflectivity. Each of the light-emitting diodes is provided underneath each of the optical devices. The reflection sheet is provided underneath the light-emitting diodes and on a side surface of the entire module.

Preferably, each of the optical devices has a structure produced by a material of high transmittance, wherein the material of high transmittance is a material selected from plastic or glass. The reflection surface of each of the optical devices can be a layer selected from a metal layer or a dielectric layer, wherein the metal layer can be a structure obtained by a treatment such as an evaporation treatment or a sputtering treatment, and the dielectric layer can be a structure obtained by stacking multiple layers of dielectric materials. In a preferred embodiment, the metal layer is a structure formed by sputtering silver or aluminum and the like on the reflection surface of each of the optical devices produced by plastic and the like. In another preferred embodiment, the dielectric layer can be a structure formed by stacking TiO₂ and the like on the reflection surface of each of the optical devices produced by glass and the like. In another preferred embodiment, the side surface of each of the optical devices can be a slanted surface, wherein an included angle between the slanted surface and the normal direction of the output light of light-emitting diode ranges from 1 degree to 45 degrees.

Moreover, the reflection surface has a geometrical cross-section, wherein the reflection surface can be selected from a group consisting of V-shape, curve, circle, ellipse, and sawtooth cross-section. Preferably, the included angle between the reflection surface of V-shape cross-section and the light-emitting diode ranges from 1 degree to 60 degrees. Furthermore, the LED backlight module of the present invention can include a plurality of optical devices and corresponding light-emitting diodes, and the light-emitting diodes can be a random permutation of red, green, and blue LEDs. In a preferred embodiment, the light-emitting diodes can be white light-emitting diodes.

Besides, the LED backlight module can further include a brightness enhancement film (BEF) provided on the diffusion plate, wherein the brightness enhancement film is preferably a film or sheet produced by a material selected from polyester or polycarbonate so as to concentrate light and enhance brightness.

The present invention provides a direct-lit LED backlight module, wherein LEDs of multiple colors including red, blue, green and the like are arranged underneath the liquid crystal display; the bottom and side reflection sheet of the backlight module can reflect light into the liquid crystal display; and every LED includes an optical device that can control light paths of LED. Thus, since the reflection surface of each of the optical devices has high reflectivity, light directly emitted from LED chips can be leaded to a specific direction instead of directly emitting from the front surface. In this way, the defect of not able to achieve color-mixing with single-color light sources in the conventional technology can be eliminated. And without the problem of improving emitting light uniformity by a structure stacking a lot of layers in the conventional technology, the backlight module may thus obtain the performance of color-mixing and uniform distribution.

Therefore, the optical devices used in the present invention have simple and easily producible structure, which can solve the problems of difficult to be manufactured, high cost, and disadvantageous to industrial applicability in the conventional technology using the complicated structure and the structure stacking multiple layers. Thereby, the present invention does not generate the problem of difficult to be manufactured in the conventional technology, which can lower the cost and applied broadly to a lot of industries.

Therefore, the present invention achieves color-mixing and uniform distribution by providing a LED backlight module that is simple and easily producible, lower cost, and able to enhance industrial applicability, so as to solve all kinds of problems generated in the conventional technology.

### BRIEF DESCRIPTION OF THE DRAWINGS

The present invention can be more fully understood by reading the following detailed description of the preferred embodiments, with reference made to the accompanying drawings, wherein:

FIG. 1 is a structural schematic diagram showing an LED backlight module according to a first embodiment of the present invention;

FIG. 2 is a structural schematic diagram showing an optical device according to the first embodiment of the present invention;

FIG. 3 is a structural schematic diagram showing the LED arrangement according to the first embodiment of the present invention;

FIG. 4 is a structural schematic diagram showing an optical device in an LED backlight module according to a second embodiment of the present invention;

FIG. 5A is a structural schematic diagram showing an optical device in an LED backlight module according to a third embodiment of the present. invention;

FIG. 5B is a light distribution diagram of the optical device according to the third embodiment of the present invention;

FIG. 6A is a structural schematic diagram showing the optical device according to the first embodiment of the present invention in a sinking type LED package structure; and

FIG. 6B is a light distribution diagram of the optical device according to the first embodiment of the present invention in the sinking type LED package structure.

### DETAILED DESCRIPTION OF THE PREFERRED EMBODIMENTS

The following preferred embodiments are provided to further illustrate the present invention, and are by no means used to limit the scope of the invention.

First Embodiment

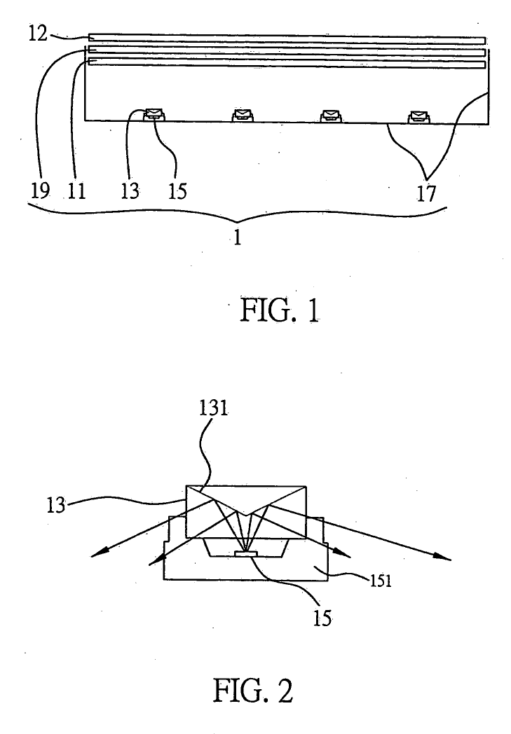

FIGS. 1 to 3 are schematic diagrams depicting a light-emitting diode backlight module according to a first embodiment of the present invention. As shown in FIG. 1, the backlight module 1 includes a diffusion plate 11, a plurality of optical devices 13, a plurality of light-emitting diodes 15, and a reflection sheet 17.

The diffusion plate 11 is provided underneath a liquid crystal display 12 to scatter and uniform diffusion of light. Wherein the liquid crystal display 12 has a conventional structure and operating mechanism that it will not be explained any further.

Each of the optical devices 13 is individually provided underneath the diffusion sheet 11, and preferably has a structure produced by a high transmitting material selected from plastic, glass or other suitable materials. Furthermore, as shown in FIG. 2, each of the optical devices 13 has a reflection surface 131 of high reflectivity. Wherein, each reflection surface 131 of the optical devices 13 has a layer of metal layer, dielectric layer, or other equivalent layers of mirror, and the included angle between the reflection surface 131 and each of the light-emitting diodes 15 ranges from 1 degree to 60 degrees. Wherein the metal layer can be a structure obtained by a treatment such as an evaporation treatment or a sputtering treatment, for example, the metal layer can be produced by sputtering silver or aluminum on the reflection surface 131 of each of the optical devices 13 formed by plastic and the like; the dielectric layer is a structure formed by stacking multiple layers of dielectric materials, for example, the dielectric layer can be formed by stacking TiO₂ on the reflection surface 131 of each of the optical devices 13 produced by glass and the like. It is not necessary to address that the treatment and material required for turning the reflection surface 131 into a mirror surface can be varied depending on requirements and are not limited in the disclosure of the embodiment.

Each of the light-emitting diodes 15 is individually provided underneath each of the optical devices 13. As shown in FIG. 3, each of the light-emitting diodes 15 has a random permutation of red (R), green (G), and blue (B) LEDs staggered arranging under the liquid crystal display. In this way, each of the light-emitting diodes 15 has one of the optical devices 13 to control light paths of LED wherein each of the optical devices 13 has a reflection surface 131 of high reflectivity to reflect light directly emitting from each of the light-emitting diodes 15 to a specific direction instead of emitting from the front surface. It is generally known by a person with general knowledge in the technical field and there is no need to address that the light-emitting diodes 15 can be selected from white light-emitting diodes.

The reflection sheet 17 is provided underneath each of the light-emitting diodes 15 and on the side edge of the entire module to reflect light emitted from each of the light-emitting diodes 15 into the liquid crystal display 12 again and increase the efficiency of light usage. It has to be understood that the diffusion plate 11 and the reflection sheet 17 are general to a person having general knowledge in the technical field and would not be explained any more.

In this embodiment, the LED backlight module 1 can further include a brightness enhancement film (BEF) 19 provided on the diffusion plate 11 to concentrate light and enhance brightness. The brightness enhancement film 19 can be, but not be limited to, a film or sheet produced by materials such as polyester or polycarbonate. Meanwhile, in other embodiments, the brightness enhancement film 19 can be integrated into the liquid crystal display 12 to lower the cost and simplify the structure. However, the modification can be easily devised and achieved by a person having general knowledge in the technical field that it is not going to be further explained here.

Since each of the optical devices has a reflection surface 131, light emitted from each of the light-emitting diodes 15 would contact different positions of the reflection surface 131. By means of the characteristic of high reflectivity resulted from reflecting light toward each direction to the bottom, it is able to obtain an anisotropic effect of uniform light dispersion. In this way, after being reflected by the optical devices 12, light emitted from each of the light-emitting diodes 15 would be reflected into the liquid crystal display 12 through the reflection sheet 17, and the diffusion plate 17 can shield few upward (i.e. toward the front surface) emitting light so as to achieve color-mixing and uniform effects.

Comparing to conventional technology using optical devices of special structures and using multiple modules for processing such that it is difficult to fulfill due to the high cost, the optical devices of the present invention merely use a substrate such as an extruded substrate and thus the processing thereof is easy. Moreover, the LED backlight module using the present invention doesn't have to satisfy the crucial condition of total internal reflection (TIR) in the conventional technology, the problem of failing to completely direct light to emit from the side surface of a product produced by substantially executing the conventional technology can be solved.

Therefore, the LED backlight module using the present invention can achieve color-mixing and uniform effects such that not only the manufacturing cost thereof is lower than the conventional technology but the easy process thereof without defects in the conventional technology, the industrial applicability may be further enhanced.

Second Embodiment

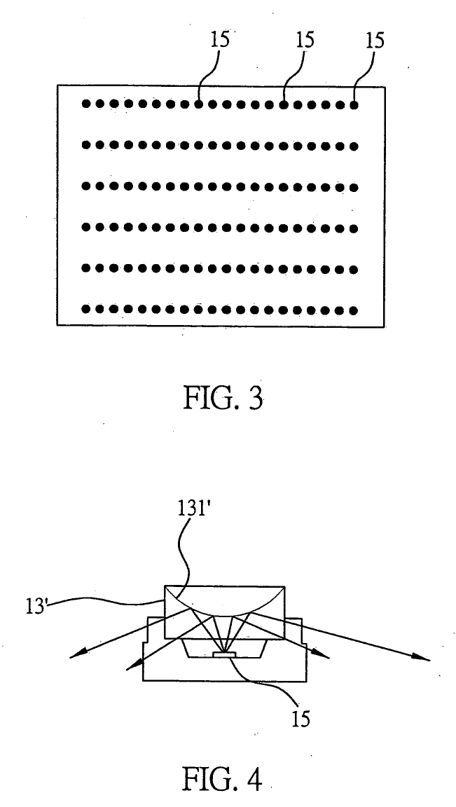

FIG. 4 is a schematic diagram depicting a light-emitting diode backlight module according to a second embodiment of the present invention. To further explain the present invention to be easily understood, the same or similar devices of the first embodiment are denoted with the same or similar symbolic references and skip further drawings and illustrations.

As shown in FIG. 4, the difference between the first embodiment and the second embodiment lies in that each of the optical devices 13 of the first embodiment have a reflection surface 131 of a V-shaped cross-section; while each of the optical devices 13′ of the first embodiment have a reflection surface 131′ of a curved cross-section.

In this embodiment, the reflection surface 131′ of a curved cross-section can further decrease light dispersed from the front surface so as to enhance the uniformity of light diffusion.

Certainly, the cross-sectional shape of the reflection surface 131 and 131′ are not limited to disclosed hereinabove V-shape and curve. Any geometric or non-geometric designs that are easy to be released may apply to the present invention, for example, circle, ellipse, sawtooth, or other polygon and the like which the curvature between two curved surfaces of the reflection surface can be different from each other and determined by desired light dispersion angles. In other words, the hereinabove disclosures such as amount and positions of LED, shapes of the reflection surface and materials and processes of coating are merely exemplary illustrations and should not be limited to the above embodiments. It has to be noted that equivalent embodiments can be easily revised by a person with general knowledge in the technical field.

Third Embodiment

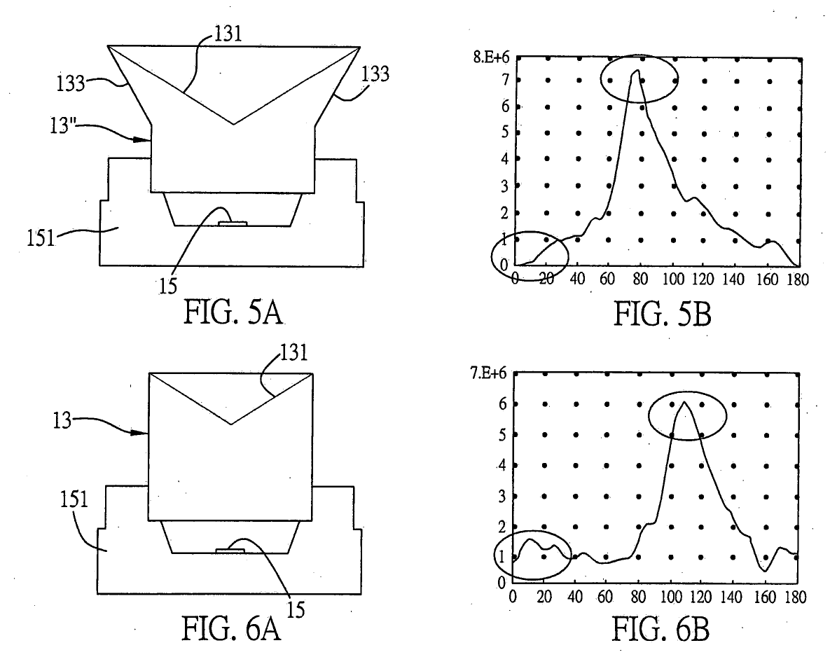

FIG. 5A is a schematic diagram depicting an LED backlight module according to a third embodiment of the present invention. To further explain the present invention to be easily understood, the same or similar devices of the first embodiment are denoted with the same or similar symbolic references and detailed drawings and illustrations are omitted.

As shown in FIG. 5A, the difference between the first embodiment and the third embodiment lies in that each of the optical devices 13 of the first embodiment has a reflection surface 131 of a V-shaped cross-section; except for a reflection surface 131 of a V-shaped cross-section (or a curved cross-section), each of the optical devices 13″ of the third embodiment has a side surface formed with a slanted surface 133 and is provided, for instance, over a sinking type LED package structure 151.

In this embodiment, since the sinking type LED package structure 151 is used, a portion of regions surrounding each of the light-emitting diodes 15 is shielded, and generates special angles of output light by shielding the light generated by each of the light-emitting diodes 15. Moreover, the light of small refraction angle is refracted to the reflection surface 131 through the slanted surface 133 provided on the side surface of each of the optical devices 13″, and subsequently refracted to a specific angle through the reflection surface 131, so as to achieve broadened output light angles. Therefore, each of the optical devices 13″ of the embodiment can be applied to both the sinking type and the overhead type LED package structure. Besides, since the output light angles can be broadened, the space between each of the optical devices 13″ and the diffusion plate can be further reduced to reduce the thickness of the entire LED backlight module.

Since each of the optical devices 13″ can be made of materials of high reflectivity such as plastic, glass, or other suitable materials, at a direction close to normal direction most of the incident light can be transmitted through the slanted surface 133; adversely, the incident light that is distant from the normal direction will be refracted to the reflection surface 131. The slanted angle of the slanted surface 133 is preferably controlled within a range that the extending direction of the light generated by each of the light-emitting diodes 15 can overlap with the slanted surface. More preferably, an included angle between the slanted surface and the normal direction of the output light of each of the light-emitting diodes 15 ranges from 1 degree to 45 degrees.

Comparative Example

Referring to FIGS. 5A, 5B, 6A, and 6B, the output light angle and intensity of the optical devices 13 of the first embodiment and the optical devices 13″ of the third embodiment are compared. The test is performed with the same conditions.

As shown in FIGS. 5A and 6A, each of the optical devices 13 and 13″ are provided over the sinking type LED package structure, wherein both each of the optical devices 13 and 13″ have the same included angle between the reflection surface 131 and each of the light-emitting diodes 15. Comparing to each of the optical devices 13, each of the optical devices 13″ is further provided with a slanted side surface 133.

As shown in FIGS. 5B and 6B, wherein the horizontal axis stands for output light angle and the vertical axis stands for output light intensity, the output light angle of each of the optical devices 13 is primarily concentrated at about 106 degrees and a small portion at about 11 degrees. The output light angle of each of the optical devices 13″ is primarily concentrated at about 75 degrees, and the output light of small angle is gradually decreased. Therefore, according to the test results, the present invention can effectively decrease the light outputted from the front surface.

Therefore, the LED backlight module of the present invention can solve defects of conventional technology by not only via optical devices control light paths to direct light emitted directly from LED chips to a specific direction instead of direct emit from the front surface such that achieve color-mixing and uniform effects; but also save production cost and enhance industrial applicability.

The embodiments described hereinabove are merely provided to exemplary illustrate the characteristic and utility of the present invention, and are not used for limiting the scope of substantial technical content of the present invention. The scope of substantial technical content of the present invention should be generally defined as the following claims, and any technical embbodiments or methods which is totally the same or is an equivalent modification of that defined in the following claims by anyone should be considered as containing in the claims.

1. A light-emitting diode (LED) backlight module comprising:
a diffusion plate;
at least an optical device provided underneath the diffusion plate and having a first reflection surface;
at least a light-emitting diode provided underneath the at least an optical device, for emitting light to the first reflection surface where first reflection of the light is performed; and
a second reflection surface provided underneath the at least a light-emitting diode, for receiving the light of the first reflection and performing second reflection of the received light.

2. The LED backlight module according to claim 1, wherein the at least an optical device has a structure made of a material of high transparency.

3. The LED backlight module according to claim 2, wherein the material of high transparency is one of plastic and glass.

4. The LED backlight module according to claim 1, wherein the first reflection surface of the at least an optical device has one of a metal layer and a dielectric layer.

5. The LED backlight module according to claim 4, wherein the metal layer has a structure formed by one of an evaporation treatment and a sputtering treatment.

6. The LED backlight module according to claim 5, wherein the metal layer has a structure formed by sputtering one of silver and -aluminum on the first reflection surface of the optical device made of plastic.

7. The LED backlight module according to claim 4, wherein the dielectric layer has a structure formed by stacking multiple layers of dielectric materials.

8. The LED backlight module according to claim 7, wherein the dielectric layer has a structure formed by stacking TiO₂ on the first reflection surface of the optical device made of glass.

9. The LED backlight module according to claim 1, wherein the first reflection surface has a geometric cross-section.

10. The LED backlight module according to claim 1, wherein the first reflection surface has a cross-section of one of V-shape, curve, circle, ellipse, and sawtooth shape.

11. The LED backlight module according to claim 10, wherein an included angle between the first reflection surface of the V-shape cross-section and the light-emitting diode ranges from 1 degree to 60 degrees.

12. (canceled)

13. The LED backlight module according to claim 1, wherein the LED backlight module includes a plurality of optical devices and a plurality of light-emitting diodes having a corresponding number to a number of the optical devices.

14. The LED backlight module according to claim 13, wherein the light-emitting diodes have a random permutation of red, green and blue LEDs.

15. The LED backlight module according to claim 1, wherein the at least a light-emitting diode is a white light-emitting diode.

16. The LED backlight module according to claim 1, further comprising a brightness enhancement film provided over the diffusion plate.

17. The LED backlight module according to claim 1, wherein a side surface of the at least an optical device is a slanted surface.

18. The LED backlight module according to claim 1, wherein the second reflection surface is provided underneath the light-emitting diode and positioned on a side surface of the LED backlight module.

19. The LED backlight module according to claim 18, wherein the second reflection surface is made of a reflection sheet.

20. The LED backlight module according to claim 1, wherein the second reflection surface is made of a reflection sheet.
